(19) United States
(12) Patent Application Publication
(10) Pub. No.: US 2009/0080488 A1
(43) Pub. Date: Mar. 26, 2009

(54) SURFACE EMITTING LASER

(75) Inventors: Hiroshi HATAKEYAMA, Tokyo (JP); Naofumi SUZUKI, Tokyo (JP); Kenichiro YASHIKI, Tokyo (JP); Takeshi AKAGAWA, Tokyo (JP); Takayoshi ANAN, Tokyo (JP); Masayoshi TSUJI, Tokyo (JP); Kimiyoshi FUKATSU, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 12/237,048

(22) Filed: Sep. 24, 2008

(30) Foreign Application Priority Data
Sep. 26, 2007 (JP) 2007-248565

(51) Int. Cl. H01S 5/187; H01S 5/18

(52) U.S. Cl. 372/50.11; 372/50.124

(57) ABSTRACT

A surface emitting laser including a semiconductor substrate, a semiconductor substrate, a first reflector formed on the semiconductor substrate, an active layer formed on the first reflector, a tunnel junction layer formed above a part of the active layer, a semiconductor spacer layer which covers the tunnel junction layer, a second reflector formed on the semiconductor spacer layer in a region above the tunnel junction layer, a first electrode formed in the periphery of the second reflector on the semiconductor spacer layer, and a second electrode electrically connected to a layer lower than the active layer, wherein a layer thickness of the semiconductor spacer layer in the region directly above the tunnel junction layer is thinner than the layer thickness of the semiconductor spacer layer in the region directly below the first electrode.

This application is based upon and claims the benefit of priority from Japanese patent application No. 2007-248565, filed on Sep. 26, 2007, the disclosure of which is incorporated herein in its entirety by reference.

### BACKGROUND OF THE INVENTION

1. Field of the Invention

The present invention relates to surface emitting lasers, and in particular, it relates to tunnel-junction VCSELs.

2. Description of the Related Art

In recent years, a vertical cavity surface emitting laser (VCSEL) provided with advantages such as high speed, small size, low power consumption and low cost has been extensively developed as a light source for optical communications. A device that can be modulated at a high speed to the extent of 1 to 10 Gbps (gigabit per second) has been put into practical use.

The most common configuration in the surface emitting laser is the one referred to as an oxide-confined VCSEL based on a GaAs substrate. The oxide-confined VCSEL has a laminated structure integrally forming an active layer and semiconductor distributed Bragg reflectors (DBR) positioned above and below the active layer on the GaAs substrate by epitaxial growth. Such device has a common structure in which the upper and lower DBRs are semiconductors and the current injection into the active layer is performed through the DBRs. The oxide-confined VCSEL is characterized in that the manufacturing process is simple. It is because of, for example, no need for buried re-growth in the formation of a current-confinement structure.

Surface emitting lasers include a tunnel junction type using a tunnel junction as a current-confinement structure. The surface emitting laser of the tunnel junction type can accelerate the speed and reduce the power consumption by the lowering of the resistance. Further, the surface emitting laser of the tunnel junction type has a structure typically disclosed in Markus Ortsiefer et al, [2.5 mW Single-Mode Operation of 1.55-μm Buried Tunnel-junction VCSELs], IEEE PHOTONICS TECHNOLOGY LETTERS, VOL. 17, No. 8, August, 2005. That is, with an InP substrate as a base, it is used as a surface emitting laser for long wavelength band such as a lasing wavelength 1.3 μm band or 1.55 μm band or the like for telecommunications application.

The inventors have developed tunnel-junction VCSELs with a GaA_{S} substrate as a base, the substrate is generally used for the oxide-confined VCSEL. An active layer of the tunnel-junction VCSELs includes strained quantum wells with InGaAs well layers, which have excellent optical gain properties. And a tunnel junction structure is used as a current-confinement structure. These tunnel-junction VCSELs is able to achieve a 3 db modulation bandwidth of 24 GHz which exceeds the oxide-confined VCSEL. The device structure of these tunnel-junction VCSELs is disclosed in FIG. 1 of Yashiki, et al, [1.1 μm range tunnel-junction VCSELs with 27-GHz relaxation oscillation frequency], Proceedings of optical fiber communication conference 2007, OMKI, 2007.

The device structure of the tunnel-junction VCSELs disclosed in Yashiki, et al, [1.1 μm range tunnel-junction VCSELs with 27-GHz relaxation oscillation frequency], Proceedings of optical fiber communication conference 2007, OMK1, 2007 will be described by using FIG. 6. The surface emitting laser of FIG. 6 has a semiconductor laminated structure with a lower DBR 102, an active layer 103 with a quantum-well-structure, a p-type spacer layer 104, a tunnel junction layer 105, and an n-type spacer layer 107 formed on a semiconductor substrate 101 composed of an n-type GaAs. Each layer on the n-type semiconductor substrate 101 is formed sequentially by epitaxial growth. The tunnel junction layer 105 is composed of a high concentration p-type InGaAs layer and a high concentration n-type GaAsSb layer.

The tunnel junction layer 105 has a structure in which a peripheral region other than a region serving eventually as a light emitting portion is removed by etching in the substrate plane, and after that, the whole structure is buried in an n-type spacer layer 107. Further, a high resistance portion 106 is formed by ion implantation in the periphery of a current injection region A1 before forming the n-type spacer layer 107 in order to allow the device to perform a high speed operation. Thereby, electrical capacitance can be reduced. On the semiconductor laminated structure, an upper DBR 108, a positive electrode 110, a negative electrode 111, and a polyimide layer 109 are formed. Tunnel-junction VCSELs perform lasing and a high speed modulating operation when a current is injected into the active layer 103 through the positive electrode 110 and the negative electrode 111.

The tunnel-junction VCSELs disclosed in Yashiki, et al, [1.1 μm range tunnel-junction VCSELs with 27-GHz relaxation oscillation frequency], Proceedings of optical fiber communication conference 2007, OMK1, 2007 are of great promise as a light source working at high speed, at low cost and with low power consumption. However, a problem of reliability arises. FIGS. 7A and 7B show an accelerated life test data of the tunnel-junction VCSELs. FIG. 7A shows a transition of the optical output variance under a condition with constant operating current of 10 mA at the temperature of 150° C. The number of test devices is 9 pieces. Each device has the optical output extemporaneously reduced after a certain hours of operating time.

FIG. 7B is a graph showing a relationship between a time to failure (TTF=an operation time until reaching the failure) of the test device of FIG. 7A and the device structure. The TTF of each device has a clear correlation with a distance between an opening end (end portion of the current injection region) of the tunnel junction layer 105 and the positive electrode 110, that is, L_{ELEC} in FIG. 6. That is, the longer the L_{ELEC} is, the longer the TTF is.

When the faulty device was checked, it was found that a front boundary of alloyed area of the positive electrode 110 has punched through the n-type spacer layer 107 to the active layer 103. In tunnel-junction VCSELs disclosed in Yashiki, et al, [1.1 μm range tunnel-junction VCSELs with 27-GHz relaxation oscillation frequency], Proceedings of optical fiber communication conference 2007, OMK1, 2007, the thickness of the n-type spacer layer is 0.23 μm. Further, the distance between the active layer and the positive electrode is approximately 0.29 μm. The positive electrode is formed of AuGe/AuGeNi by vacuum evaporation and alloy process. A lattice defect introduced into the active layer 103 by the alloy process of the positive electrode 110 gradually stretches toward the current injection region A1 by energization. It was found that when this lattice defect reaches the current injection region A1, the optical output is extemporaneously reduced.

To prevent the failure, it is conceivable to make the L_{ELEC} sufficiently long. Long L_{ELEC} causes increase of a series resistance between the tunnel junction layer 105 and the positive electrode 110. Practically, the L_{ELEC} is restricted to approximately 5 μm or less. Consequently, to make the L_{ELEC} long is not a substantial improvement measure for the failure.

It is also considered effective to make the n-type space layer 107 sufficiently thick in advance so that the front boundary of alloyed area of the positive electrode 110 does not reach the active layer 103. However, when the n-type spacer layer 107 is simply made thick, a distance L_{CAVITY} between the upper and lower DBRs becomes long. That is, an effective cavity length becomes long, and there arises a problem that rapidity is spoiled.

The problem in tunnel-junction VCSELs as described above has not been noticed hitherto. In a common oxide-confined VCSEL, an upper DBR layer is formed of a p-type semiconductor. Further, an upper electrode is formed of Ti/Au and the like of non-alloy. Hence, there is no need to consider stretching a defect which was induced by alloy process. Granting that the progress of the alloy occurs, no defect is caused to an active layer 103 because a p-type DBR layer of approximately 3 to 4 μm in thickness is present between the upper electrode and the active layer 103. Even when an upper DBR layer is formed of an n-type semiconductor and alloyed ohmic electrode is used as the upper electrode, by the same token, no defect is caused to the active layer 103.

On the other hand, this problem has not been noticed even in a surface emitting laser for long waveband whose upper DBR is formed with dielectric material/semiconductor and has a tunnel-junction. The following three points are cited as the main reasons. The first reason is due to an n-electrode material. Ti/Au and the like of non alloy can be used as the n-electrode material in a long waveband surface emitting laser based on InP. Hence, there is no need to consider the effect on the reliability by the progress of the front boundary of alloyed area.

The second reason is due to a semiconductor material. In the long waveband surface emitting laser, InGaAs small in band-gap can be used as a semiconductor layer, in which an electrical contact with the upper n-electrode is performed. Further, the n-type spacer layer is formed of InP. Inside the semiconductor containing In, reproduction of crystal defects is restrained. Even when crystal defects based on the upper n-electrode are present, the extension of the defects into the active layer is suppressed. Hence, the crystal defects hardly bring about an effect on the reliability of the device.

The third reason is due to a lack of study for realizing a rapid operation. In the long waveband surface emitting laser, the study for realizing a high speed operation exceeding 10 Gbps has not been sufficiently conducted. This is because an optical gain is not sufficient owing to the characteristics of the material in the long waveband surface emitting laser, thus a high speed operation exceeding 10 Gbps can be hardly expected originally. When modulation speed is 10 Gbps or less, the necessity of making the L_{CAVITY} sufficiently short does not exist at all. Hence, the problem cannot be noticed. With respect to Ye Zhou et al, [Novel Surface Emitting Laser using High-Contrast Subwavelength Grating], Conference Digest of Semiconductor Laser Conference 2006, WB4, 2006, a description will be made later.

### SUMMARY OF THE INVENTION

An exemplary object of the invention is to provide a surface emitting laser capable of performing at a high speed operation and excellent in reliability.

An exemplary aspect of the invention includes a semiconductor substrate, a semiconductor substrate, a first reflector formed on the semiconductor substrate, an active layer formed on the first reflector, a tunnel junction layer formed above a part of the active layer, a semiconductor spacer layer which covers the tunnel junction layer, a second reflector formed on the semiconductor spacer layer in a region above the tunnel junction layer, a first electrode formed in the periphery of the second reflector on the semiconductor spacer layer, and a second electrode electrically connected to a layer lower than the active layer, wherein a layer thickness of the semiconductor spacer layer in the region directly above the tunnel junction layer is thinner than the layer thickness of the semiconductor spacer layer in the region directly below the first electrode.

### BRIEF DESCRIPTION OF THE DRAWINGS

The above and other objects, features and advantages of the present invention will become more apparent from the following detailed description when taken in junction with the accompanying drawings wherein:

FIG. 1 is a structure of a surface emitting laser device according to a first embodiment of the present invention;

FIG. 2A is a graph showing an optical field distribution in a direction to an optical cavity in an oxide-confined VCSEL;

FIG. 2B is a graph showing an optical field distribution in a direction to an optical cavity in a surface emitting laser device and

FIG. 3 is a view showing a comparison between the oxide-confined VCSEL and the surface emitting laser of the present invention;

FIGS. 4A to 4G are partial sectional views schematically showing manufacturing processes of the surface emitting laser device according to the first embodiment of the present invention;

FIG. 5 is a partial sectional view schematically showing a structure of the surface emitting laser device according a second embodiment of the present invention;

FIG. 6 is a partial sectional view schematically showing the structure of a surface emitting laser device relating to the present invention; and

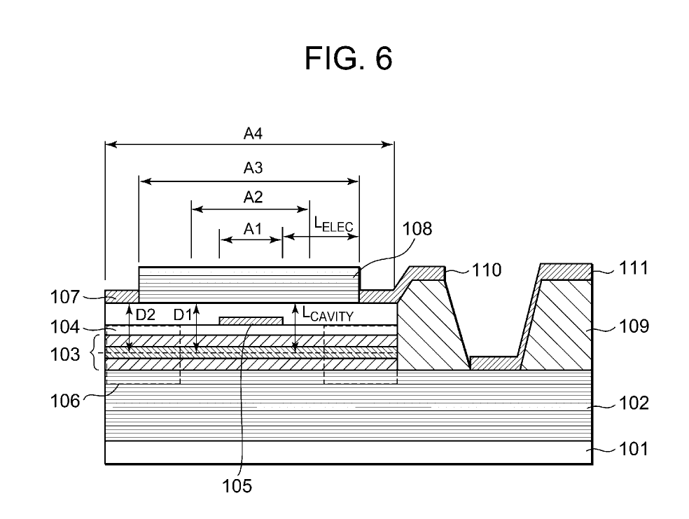

FIGS. 7A and 7B are an experimental data showing the reliability of a device relating to the present invention.

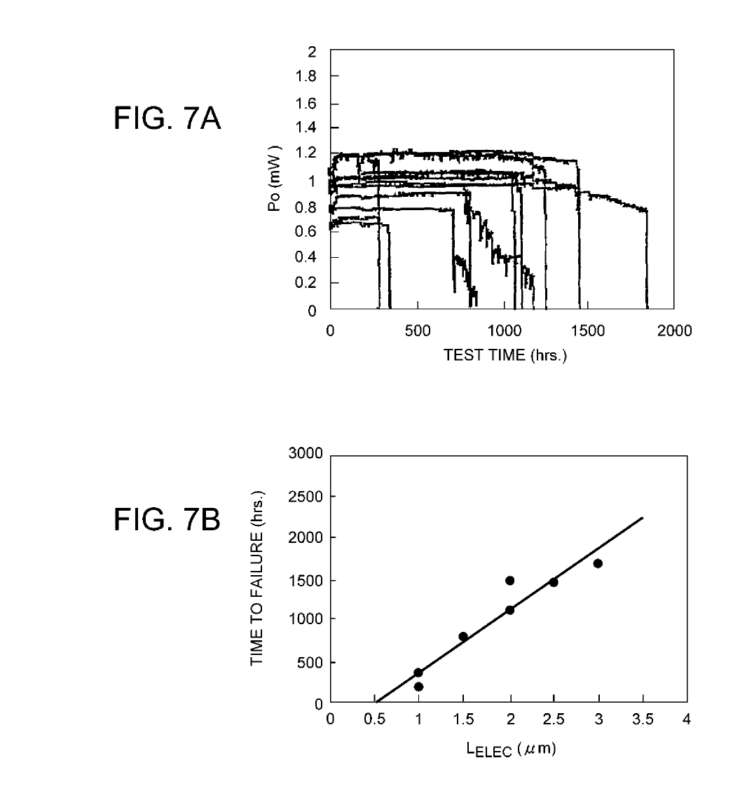

### DETAILED DESCRIPTION OF THE PREFERRED EMBODIMENTS

Specific embodiments applied with the present invention will be described in detail below with reference to the drawings. However, the present invention is not restricted to the following embodiments. Further, to make the description clear, the following description and drawings are appropriately simplified.

### First Embodiment

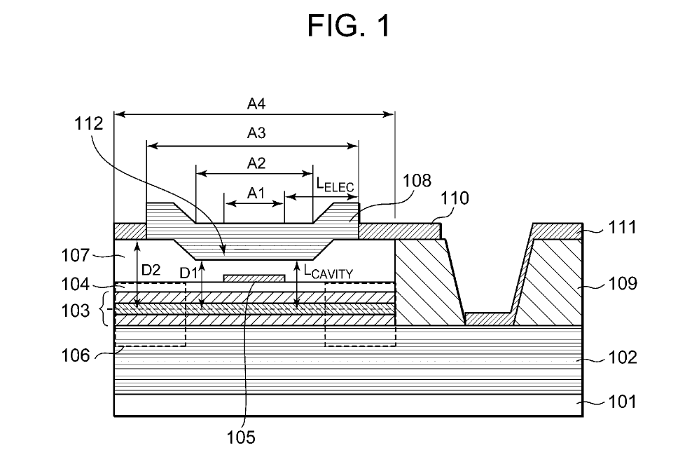

FIG. 1 is a sectional view of a surface emitting laser device according to a first embodiment of the present invention. The surface emitting laser according to the present embodiment has a semiconductor laminated structure including a lower DBR 102, an active layer 103 with a quantum-well-structure, a p-type spacer layer 104, a tunnel junction layer 105, and an n-type spacer layer 107 on a semiconductor substrate 101 composed of an n-type GaAs. Each layer of this semiconductor laminated structure is formed sequentially by epitaxial growth. The tunnel junction layer 105 is composed of a high concentration p-type InGaAs layer and a high concentration n-type GaAsSb layer.

The lower DBR 102 has, for example, a structure sequentially laminated with a low refractive index layer made of a Si dope (concentration 8×10¹⁷ cm⁻³) n-type AlAs and a high refractive index layer made of a Si dope (concentration 8×10¹⁷ cm⁻³) n-type GaAs. Specifically, the lower DBR 102 can be provided with a periodic structure laminated with 40.5 pairs when the low refractive index layer and the high refractive index layer having an optical thickness of λ/4 respectively are made into one pair. The “40.5 pairs” means a structure with one layer of the low refractive index layer added to 40 pairs.

The active layer 103 is, for example, provided with a quantum well (peak of the light emitting spectrum is 1.07 μm) comprising In_{0.3}Ga_{0.7}As/GaAs as a quantum well and comprising GaAs as a barrier layer. The active layer 103 is further provided with an n-type SCH layer and a p-type SCH layer arranged at opposing ends of the quantum well. The optical thickness of the whole active layer 103 is desirable to be set to 1λ. The λ represents a medium inner length of lasing wavelength. For example, when a lasing wavelength is set to Λ, and a refractive index in a medium is set to n, λ=Λ/n.

The p-type spacer layer 104 is, for example, made of a C-dope (concentration 8×10¹⁷ cm⁻³) p-type GaAs. Its optical thickness is desirable to be set to approximately λ/4.

When a strained quantum-well-structure active layer using InGaAs for a well-layer is formed on a GaAs substrate, a range of the lasing wavelength is as follows. That is, the range of the lasing wavelength suitable for realizing the high speed modulating operation is approximately 1.0 to 1.2 μm. When the lasing wavelength is less than 1.0 μm, it is hard to obtain merits of the increase in the gain by a strained quantum-well-structure. In the meantime, when the lasing wavelength exceeds 1.2 μm, deterioration of reliability is concerned due to the large amount of crystal strain. However, when InGaAs ternary substrate having a lattice constant larger than GaAs is available as a substrate, the situation is different. That is, while the high reliability is maintained, the lasing wavelength can be extended to a long wavelength of approximately 1.34 μm. However, when the lasing wavelength is made further longer, an effective cavity length of the surface emitting laser to be described later is also made long. This results in the lowering of the modulation speed of the surface emitting laser.

The tunnel junction layer 105 includes a high concentration p-type InGaAs layer and a high concentration n-type GaAsSb layer. For example, the layer 105 includes a high concentration p-type layer of approximately 15 nm in thickness made of a C-dope (concentration 1×10²⁰ cm⁻³) p-type GaAs and a high concentration n-type layer of approximately 15 nm in thickness made of a Si dope (concentration 2×10¹⁹ cm⁻³) n-type GaAs.

Further, the tunnel junction layer 105 has the periphery of a portion serving eventually as a current injection region A1 removed by etching in the substrate plane. The peripheral portion of the current injection region A1 has a high resistance portion 106 formed by ion implantation. As a result, device capacitance is reduced, and the high speed operation of the device can be achieved. The n-type spacer layer 107 buries the whole surface of the semiconductor laminated structure formed with the tunnel junction layer 105 and the high resistance portion 106.

In the current injection region A1 serving as a forming region of the tunnel junction layer 105, the current injection into the active layer 103 is performed through the tunnel junction layer 105. In the meantime, in the region where no tunnel-junction layer is formed, the n-type spacer layer 107 and the p-type spacer layer 104 are adjacent to each other. That is, the region where no tunnel-junction layer is formed includes a p/n junction of the normal reverse bias, thereby blocking the current. By this current-confinement structure, a light emission occurs in the active layer 103 in the vicinity of the current injection region A1.

The n-type spacer layer 107 is, for example, made of the Si dope (concentration 8×10¹⁹ cm⁻³) n-type GaAs. The n-type spacer layer 107 has a recess portion 112 in a part directly above the current injection region A1 and the vicinity thereof. By this recess portion 112, in the vicinity of the current injection region A1, the distance between the upper surface of the n-type spacer layer 107 and a center plane of the active layer 103 in the direction to the optical cavity can be made short as shown by D1 in FIG. 1. In the meantime, directly below the positive electrode 110, this distance can be made long as shown by D2 in FIG. 1. The center plane of the active layer 103 is a plane passing through the central region of the active layer 103. Specifically, if the layer thickness of the active layer 103 is X, a distance in the laminating direction between the lower surface of the active layer 103 and the center plane of the active layer 103 is approximately X/2.

Specifically, in the current injection region A1 which is directly above the tunnel junction layer 105, the distance D1 is equivalent to the optical thickness 1λ. Further, the distance L_{CAVITY} between the upper and the lower DBRs is desirable to be equivalent to 3λ/2 in optical thickness. Thereby, in the current injection region A1 and the vicinity thereof, a short L_{CAVITY} required for the high speed operation of the surface emitting laser can be realized. The L_{CAVITY} for realizing a high speed modulation exceeding 10 Gbps is desirable to be 5λ/2 or less in optical thickness. A variance of layer thickness of the n-type spacer layer 107 in the forming region of the tunnel junction layer 105, that is, the current injection region A1 is desirable to be λ/10 or less in optical thickness. The variance in layer thickness means a difference between the maximum layer thickness and the minimum layer thickness in the region.

In the outside region rather than the current injection region A1 the n-type spacer layer 107 is not etched. Hence, the distance D2 between the positive electrode 110 and the center plane of the active layer 103 is desirable to be 1.0 μm or more in thickness. Thereby, a structure can be realized, in which the front boundary of alloyed area in the positive electrode 110 is unable to reach the active layer 103. As a result, the problem of the reliability in the tunnel-junction surface emitting laser concerned in Yashiki, et al, [1.1 mm range tunnel-junction VCSELs with 27-GHz relaxation oscillation frequency], Proceedings of optical fiber communication conference 2007, OMK1, 2007 can be solved. As described above, the tunnel-junction VCSELs according to the present invention can achieve both the high speed modulation speed exceeding 20 Gbps and the high reliability.

On the semiconductor laminated structure, after forming the recess portion 112, the upper DBR 108, the positive electrode 110, a negative electrode 111, and a polyimide layer 109 are formed. Through the positive electrode 110 and the negative electrode 111, the current injection into the active layer 103 is performed. Based on this, the lasing and the high speed modulating operation of the surface emitting laser are performed. Here, both the positive electrode 110 and the negative electrode 111 are n-electrodes, and are alloy electrodes made of Au/Ge/Ni.

The upper DBR 108 is desirable to be a layer structure of three cycles formed of a SiO₂ low refractive index layer (thickness of 181.2 nm) of λ/4 in optical thickness and a Si high refractive index layer (thickness of 71.5 nm) of λ/4 in optical thickness. Material of the high refractive index layer is, for example, Si, Sb₂S₃, ZnSe, CdS, ZnS, or TiO₂. Material of the low refractive index layer is, for example, SiO₂, SiNx, MgO, CaF₂, MgF₂ or Al₂O₃. In consideration of the lasing wavelength, an appropriate transparent material is selected.

As a device constituting the semiconductor laminated structure, for example, N, P, or Te, may be used. The semiconductor substrate 101 is also not restricted to GaAs. The semiconductor substrate 101 may be formed of, for example, InP, InGaAs, or GaN.

Next, characteristics of tunnel-junction VCSELs according to the present invention in comparison to the oxide-confined VCSELs will be described. There are mainly two characteristics. The first characteristic is that the tunnel junction layer 105 is used as the current-confinement structure. The tunnel junction is formed of a high concentration p/n junction. When a reverse bias is applied to this junction, by a tunnel effect, an electron current can be converted into a hole current. This tunnel junction is formed in the p-type semiconductor layer in the vicinity of the active layer 103, so that the outermost layer of the semiconductor layer can be made into an n-type semiconductor. As a result, the reduction in device resistance and absorption loss, the suppression of non-uniform injection, and the like can be expected. The second characteristic is that the upper DBR 108 includes a high Δ Si/SiO₂ multilayer film. The high Δ means a high refractive index difference. When the high Δ DBR is used, the effective cavity length of VCSEL becomes short. Hence, it is possible to improve the modulation band.

An improvement effect on the high speed characteristic by the high Δ DBR will be described below. The modulation bandwidth of a direct modulation type laser is determined by a compromise between a bandwidth f_{CR} and a bandwidth fᵣ (relaxation oscillation frequency). The bandwidth f_{CR} is set down by a rate of a device resistance (R) and a parasitic capacitance (C). The bandwidth fᵣ is set down by the gain characteristic of a current injection device. In the oxide-confinement VCSEL, the bandwidth f_{CR} can be raised to 20 GHz or more by using an appropriate means. What is meant by the appropriate means is a reduction of R through the optimization of the semiconductor structure by the epitaxial growth, a reduction of C through the polyimide planalization and the ion implantation structure, and the like. However, fr remains approximately 16 GHz. Hence, in the oxide-confined VCSEL, a main restriction factor for realizing the high speed operation of 20 Gbps or more is fr. The fr is shown in the following formula.

$$fr ∝ \frac{1}{2 π} \sqrt{( \frac{d g}{d n} \cdot \frac{1}{Vp} )} \qquad ( 1 )$$

Wherein dg/dn is a differential gain, and Vp is a mode volume of the lasing light. From the formula (1), it is apparent that the Vp is smaller, the Fr is higher. The effect of the reduction in the device resistance and the absorption loss and the like by the tunnel junction structure leads to the suppression of self-heating of the device. That is, this effect appears as an improvement effect of the term of dg/dn in the formula (1).

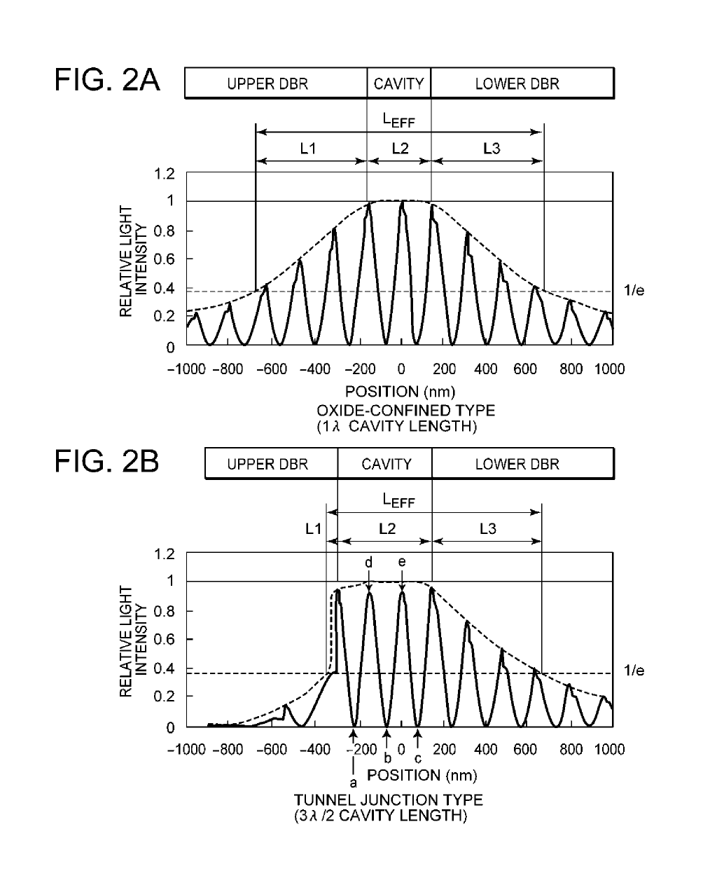

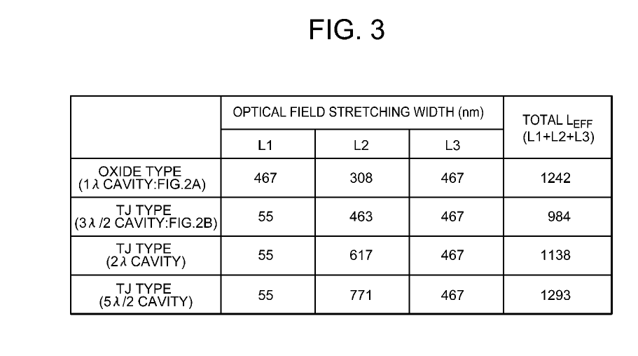

In the tunnel-junction VCSELs according to the present invention, an optical cavity direction component in the mode volume Vp is abridged by the high Δ upper DBR. Hence, it was found that fr increases. This will be described below by using FIGS. 2A and 2B. FIG. 2A shows an intensity distribution of an optical field in the cavity direction in the oxide-confined VCSEL having an optical thickness of 1λ as the distance (L_{CAVITY}) between the upper and lower DBRs. FIG. 2B shows an intensity distribution of the optical field in the cavity direction in the tunnel-junction (TJ) VCSEL of 3λ/2 in L_{CAVITY}. The axis of abscissas shows a position in the thickness direction, and the axis of ordinate shows a relative light intensity. The plus side of the axis of abscissas is a substrate side. The optical field and its envelope are shown by a solid line and a broken line, respectively. Both of the structures form an optical field of the standing wave shape by the upper and the lower DBRs sandwiching the active layer 103.

An effective cavity length (L_{EFF}) is often used as a index for discussing the mode volume in the optical cavity direction in the VCSEL. The L_{EFF} is defined as a width of the region whose relative light intensity becomes 1/e or more. Here, e is the base of natural logarithm. The region where the relative light intensity is 1/e or more means a sum total of a portion L1, L2, L3 which are shown in FIGS. 2A and 2B. The portion L1 belongs to the upper DBR. The portion L2 belongs to the active layer. The L3 belongs to the lower DBR in the laminated structure.

In the oxide-confined VCSEL of FIG. 2A, both of the upper and lower DBRs are formed of an AlGaAs/GaAs based semiconductor. Further, stretching widths L1 and L3 of the optical field toward both regions are approximately 467 nm, respectively. Further, the width of the optical field in the cavity portion including the active layer and having an optical thickness of 1λ is 308 nm. That is, the L_{EFF} in vacuum is approximately 1242 nm. The structure of the oxide-confined VCSEL shown here is a structure of the device provided with a design capable of performing a high speed operation of 20 Gbps or more. The fr of this structure is 16 GHz, and the 3 dB modulation band is 20 GHz.

In the meantime, in the tunnel-junction VCSEL of FIG. 2B, the lower DBR is formed by the AlGaAs/GaAs based semiconductor similarly to the oxide-confined VCSEL. For this reason, the stretching width L3 of the optical field into this region is approximately 467 nm. Meantime, the upper DBR 108 is formed with the high Δ multilayer film made of Si/SiO₂. Hence, the optical field intensity is drastically reduced. The stretching width L1 is approximately 55 nm, and is made sharply short as compared with the stretching width L1 of the oxide-confined VCSEL. The width L2 of the optical field in the cavity portion including the active layer, the tunnel-junction, and the like is the optical thickness of 3λ/2. That is, the width L2 of the optical field is approximately 463 nm, and is longer than the width L2 of the optical field of the oxide-confined VCSEL. As a result, the L_{EFF} in the present device becomes 984 nm in vacuum, and is shorter than the L_{EFF} of the oxide-confined VCSEL. The structure of tunnel-junction VCSEL shown here is a structure of the device whose aperture diameter of the tunnel-junction portion is 5 μm. The fr of the structure of this tunnel-junction VCSEL is a high frequency such as 23 GHz. This value cannot be achieved by the oxide-confined VCSEL. The 3 dB modulation band is 24 GHz, and the high speed operation at 20 Gbps or more is confirmed.

The tunnel junction layer 105 has a large optical absorption coefficient for the lasing light. Therefore, it is desirable to select a portion as low as possible in light intensity inside the cavity to arrange the tunnel junction layer 105. The light intensity distribution inside the cavity is distributed on the standing wave as illustrated in FIG. 2B. The tunnel junction layer 105 is desirable to be positioned on the nodes (a, b, and c) of the standing wave. The active layer 103 is desirable to be positioned on the antinodes (d and e) of the standing wave high in light intensity. Further, in view of the reliability, the active layer 103 and the tunnel junction layer 105 are desirable to be isolated from each other as much as possible. Hence, in FIG. 2B, for example, the active layer 103 is desirable to be positioned at d, and the tunnel junction layer 105 is desirable to be positioned at c.

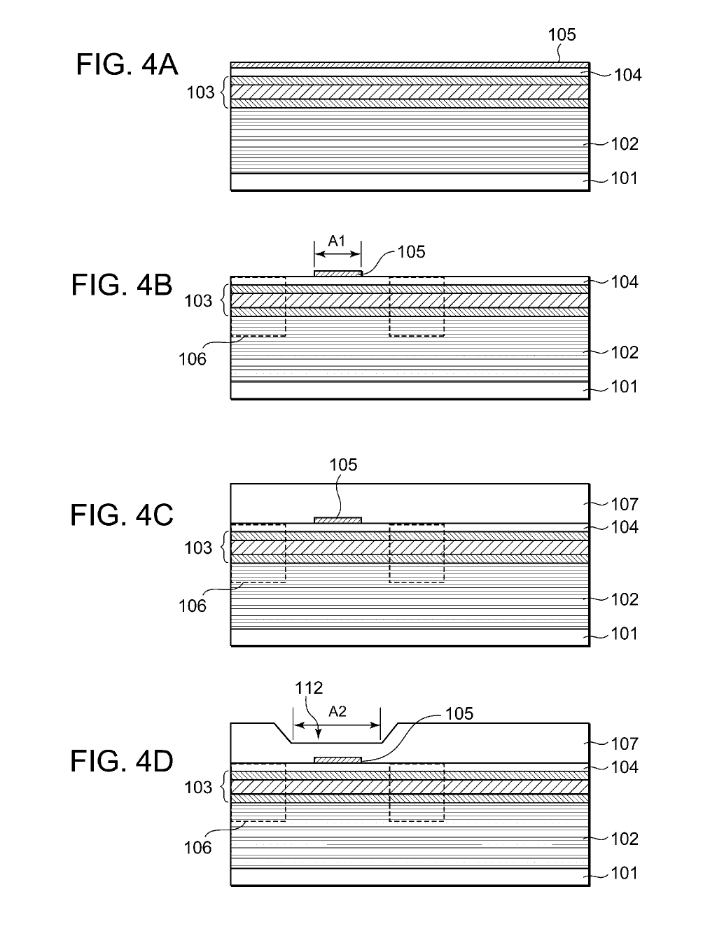

The L_{EFF} comparison of both structures was put together in FIG. 3. Here, with respect to the tunnel-junction (TJ) VCSEL, the L_{EFF} of the structure whose cavity length L_{CAVITY} is 2λ and 5λ/2 is also shown. FIG. 3 shows that the L_{EFF} is approximately 1293 nm in the structure of the tunnel-junction VCSEL whose cavity length L_{CAVITY} is approximately 5λ/2. This is a length of the same extent as the oxide-confined VCSEL. That is, even in the tunnel-junction VCSEL whose cavity length L_{CAVITY} is approximately 5λ/2, it is apparent that fr=16 GHz, the modulation bandwidth=20 GHz, and the operation speed=20 Gbps or more can be realized.

As described above, in the tunnel-junction VCSELs according to the present invention, the mode volume can be made small by the high Δ DBR. Hence, the fr increases as compared with the oxide-confined VCSEL.

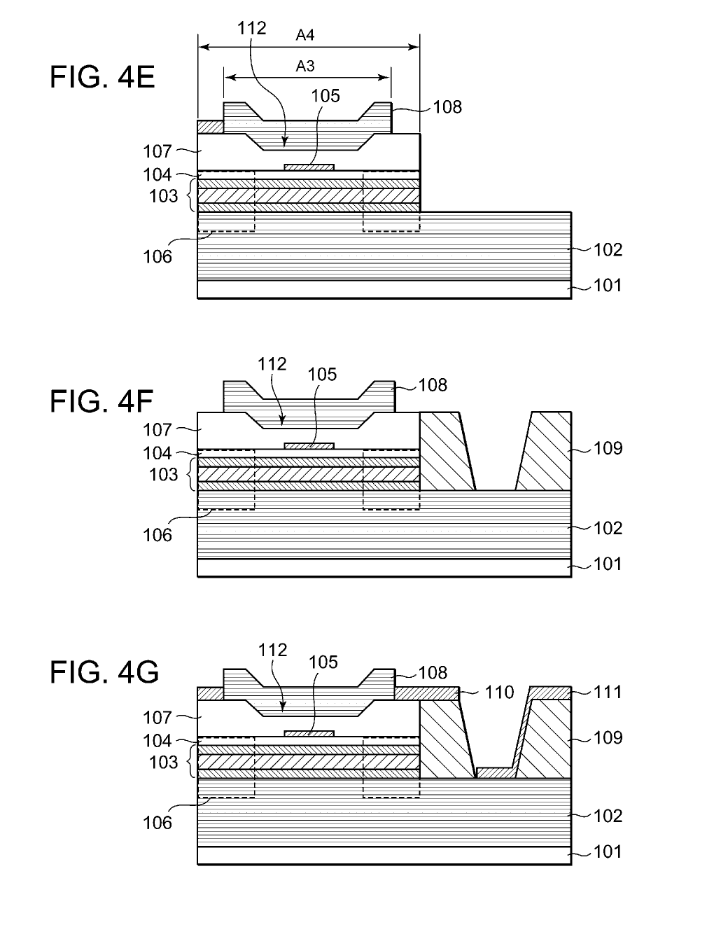

Next, a manufacturing method of the surface emitting laser device shown in FIG. 1 will be described with reference to FIGS. 4A to 4G.

A first process is shown in FIG. 4A. That is, on the n-type semiconductor substrate 101, the semiconductor laminated structure from the lower DBR 102 to the tunnel junction layer 105 is formed by Metal-Organic Vapor Phase Epitaxy (MOVPE). The lower DBR 102 is a first reflector. This semiconductor laminated structure includes at least the lower DBR 102, the active layer 103, the p-type spacer layer 104, and the tunnel junction layer 105. To improve the device characteristic, an additive semiconductor layer such as a gradient composition layer may be appropriately inserted.

The next process is shown in FIG. 4B. That is, a resist pattern is formed by photo-lithography. Further, the tunnel junction layer 105 other than the current injection region A1 is removed by etching process. At this time, an etching depth is desirable to be approximately 30 nm. Although a planar shape of the current injection region A1 can be set to the circular shape of approximately 3 to 10 μm in diameter, but this is not limitative. After the etching process, the high resistance portion 106 is formed by oxygen ion implantation in the peripheral portion of the current injection region A1. Here, the high resistance portion 106 is desirable to be a region further outside than a diameter 12 μm with the middle of the current injection area A1 as a center.

The next process is shown in FIG. 4C. That is, by the crystal growth process of the second time, the n-type spacer layer 107 made of the Si dope n-type GaAs is formed. The thickness of the n-type spacer layer 107 is set to 0.94 μm. By the formation of the n-type spacer layer 107, a current block structure of a buried tunnel-junction type device is formed. The thickness of this n-type spacer layer 107 is desirable to be the minimum thickness within a range where the crystal defect of the front boundary of alloyed area does not reach the active layer 103. The crystal defect of the front boundary of the alloyed area is generated by the formation of the positive electrode 110, an alloy process, and the like. We confirmed that, when the distance D2 from the center plane of the active layer 103 to the positive electrode 110 is approximately 1.0 μm or more, sufficient reliability can be secured. At this time, the thickness of the n-type space layer 107 made of GaAs becomes approximately 0.94 μm. By changing the material of the n-type spacer layer 107 to the material in which the crystal defects hardly proliferate compared to GaAs, the thickness of the n-type spacer layer 107 can be made thin. As the material in which the crystal defect hardly proliferates compared to GaAs, for example, there are InGaAs, InGaP, and InGaAsP, to which a certain amount of In is contained. Further, the n-type spacer layer may be configured by multi-layers, and at least one layer thereof may be structured to be added with In.

The next process is shown in FIG. 4D. That is, the n-type spacer layer 107 in the current injection region A1 and its periphery is formed with an recess portion 112 which is a recess sank in the tunnel junction layer direction by etching process. By etching, the thickness of the n-type spacer layer 107 in a region directly above the current injection region A1 and the peripheral portion thereof is desirable to be set to the optical thickness of λ/4. The bottom region A2 of this recess portion 112 is desirable to be approximately 0.5 μm to 6 μm larger than the diameter of the current injection region A1. Thereby, all the lasing modes contained in the lasing light are not brought into contact with this recess portion 112.

The next process is shown in FIG. 4E. That is, forming the upper DBR 108 serving as a second reflector on the surface of the n-type spacer layer 107 by sputtering method. After that, by using photo-lithography and etching process, the upper DBR 108 of the outside region rather than the inner diameter region A3 of the positive electrode 110 is removed. Further, by using photo-lithography and etching process, a mesa was formed. That is, the semiconductor laminated structure of the outer periphery was removed until the depth reaching the lower DBR 102. A diameter of a mesa forming region A4 is, for example, set to 22 μm.

The next process is shown in FIG. 4F. That is, a polyimide layer 109 is formed by a photo-lithography process. The polyimide layer 109 is a structure for reducing pad capacitance of the positive electrode 110 required at the time of the high speed operation.

The final process is shown in FIG. 4G. That is, the positive electrode 110 and the negative electrode 111 made of Au/Ge/Ni are formed. After that, an electrode alloy is performed. Thereby, the surface emitting laser device according to the present embodiment shown in FIG. 1 is completed. The electrode alloy can be performed, for example, under the condition of the temperature 375° C. for ten seconds. The negative electrode 111 is electrically connected to the lower DBR 102. FIG. 4G also shows the layer thickness of the n-type spacer layer 107 in a region directly above the current injection region A1 and the peripheral portion thereof, that is in a region directly above the tunnel junction layer and the peripheral portion thereof, is thinner than the layer thickness of the n-type spacer layer 107 in the region directly below the positive electrode 110.

The semiconductor material and the manufacturing method used in the present invention is not restricted to the present embodiment. The film formation of the upper DBR 108 and the lower DBR 102 may be performed using, for example, a method such as sputtering method such as RF sputtering, reactive sputtering, or a method such as an electron beam evaporation method, a CVD method (Chemical Vapor Deposition), ion-beam assist deposition, MOVPE, and Molecular Beam Epitaxy (MBE).

The aspect of the lower DBR 102 may not be a semiconductor DBR. After removing a part of the semiconductor substrate 101 by the etching, the multilayer films composed of the semiconductor/dielectric material similarly to the upper DBR 108 can be formed as the lower DBR 102. Alternatively, by using wet oxidation, the upper DBR 108 and the lower DBR 102 may be turned into the DBR composed of the semiconductor/wet oxide film. Further, they may be turned into the DBR composed of the semiconductor/air space which is formed by selectively removing the semiconductor layers which correspond to low index layers of the DBR. Further, the reflector other than the DBR such as vacuum evaporated metal films may be used.

Further, when the upper DBR 108 and the lower DBR 102 are formed with the semiconductor, a potential barrier relax layer may be introduced between a low refractive index layer having a large band gap and a high refractive index layer having a small band gap. The barrier relax layer has an intermediate band gap for relaxing the discontinuity of a potential barriers for electrons and halls. As a result, the carriers are easily injected, and a device resistance can be reduced.

### Second Embodiment

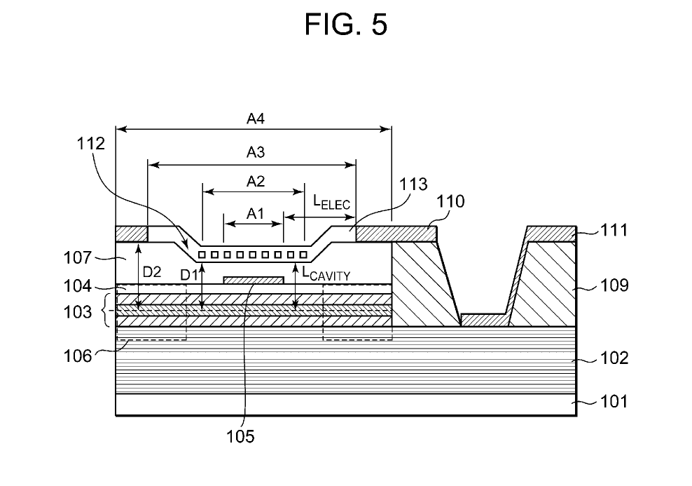

FIG. 5 is a sectional view of a surface emitting laser device of a second embodiment of the present invention. In the device structure of the present embodiment, as an upper reflector, instead of DBRs, subwavelength diffractive gratings 113 are used. The subwavelength diffractive gratings are, for example, formed of semiconductor/dielectric material, and include a periodic planar structure of the cycle shorter than the lasing wavelength. As an example of reports on the surface emitting laser including the subwavelength diffractive gratings as an upper reflector, for example, Ye Zhou et al, [Novel Surface Emitting Laser using High-Contrast Subwavelength Grating], Conference Digest of Semiconductor Laser Conference 2006, WB4, 2006 can be cited. The surface emitting laser of Ye Zhou et al, [Novel Surface Emitting Laser using High-Contrast Subwavelength Grating], Conference Digest of Semiconductor Laser Conference 2006, WB4, 2006 is formed of AlGaAs and an air space. The subwavelength diffractive gratings provided in a semiconductor layer structure of an active layer upper portion have a laser planar structure of a periodic stripe-shape below the lasing wavelength. Further, the upper and lower layers of the subwavelength diffractive gratings are also formed of the air space. In Ye Zhou et al, [Novel Surface Emitting Laser using High-Contrast Subwavelength Grating], Conference Digest of Semiconductor Laser Conference 2006, WB4, 2006, single mode lasing that is deflection-controlled by using the subwavelength diffractive gratings is obtained.

The structure of the present embodiment uses the subwavelength diffractive grating 113 instead of the DBR as the upper reflector. Except for this point, the structure is the same as that of the first embodiment. In the present embodiment, the subwavelength diffractive grating 113 is formed instead of the process described in FIG. 4E of the first embodiment. That is, after forming a recess portion 112 described in FIG.4D, on the surface of the semiconductor layer, a periodic multilayer based on SiO₂ layers and Si layers are deposited by sputtering. The thickness of SiO₂ layer is 180 nm, and the thickness of Si layer is 80 nm. After that, by electron beam exposure and dry etching, the subwavelength diffractive grating 113 composed of a stripe-shaped periodic structure is formed. At this time, the stripe-shaped periodic structure is a structure arranged with Si layer of 80 nm in width at 260 nm pitches. This stripe-shaped periodic structure of Si layer is buried in SiO₂ layer of 360 nm in thickness by the sputtering process to be completed. Other processes are the same as those of the first embodiment.

In view of the high speed operation, the reflector using this subwavelength diffractive grating 113 has a reflection coefficient of 99% or more. Hence, the film thickness can be made thinner than the reflector using the DBR. As a result, the effective cavity length L_{EFF} of the surface emitting laser is made shorter. Further, by the increase of fr, further improvement of high speed modulation characteristic can be expected.

Characteristics of the present invention in view of the device resistance and a heat dissipation property will be described. A surface emitting laser of the related technology using subwavelength diffractive gratings for an upper reflector has an upper electrode formed on a p-type semiconductor. Further, current injection into an active layer 103 from an upper p-electrode of the periphery of a light emission region is performed from the lateral direction through a thin p-type spacer layer 104. Hence, there has been a problem that the uneven injection of carriers easily causes the spatial hole-burning. Increase of the device resistance also creates a big problem. Further, by increase of the device resistance, heating dissipation value also increases. However, the subwavelength diffractive gratings are usually high in heat resistance, and are provided with the dielectric material, the air, and the like of a bad heat dissipation property in the structure. This creates a problem that heat dissipation cannot be performed effectively. By this bad heat dissipation property, the temperature of an active layer increases, and brings out a lowering of the optical gain. Because of these problems, in the surface emitting laser of the current injection type of the related technology comprising the subwavelength diffractive grating and the upper p-electrode, it is extremely difficult to essentially realize the high speed operation exceeding 20 Gbps. In the present embodiment, by converting the carriers by the tunnel junction layer 105, the subwavelength diffractive gratings 113 are formed on the n-type spacer layer 107 which is low in device resistance and in which the uneven injection of the carriers is hard to occur. Hence, the problems of the increase in the device resistance and heat resistance due to the formation of the subwavelength diffractive grating 113 can be avoided.

As described above, according to the tunnel-junction VCSELs according to the present embodiment higher speed characteristic can be expected as compared with the tunnel-junction VCSEJs using the DBR.

Further, in the present embodiment, though the upper reflector is formed with the subwavelength diffractive gratings, even when the lower reflector is formed with the subwavelength diffractive gratings, the same effect can be obtained. From among the upper reflector and the lower reflector, rather than forming one mirror with the subwavelength diffractive gratings, forming both of the reflectors with the subwavelength diffractive gratings can strength the effect.

Further, the surface emitting laser device of the present invention, for example, can be applied to an optical interconnection such as an ultrafast adding machine.

While this invention has been described in connection with certain exemplary embodiments, it is to be understood that the subject matter encompassed by way of this invention is not to be limited to those specific embodiments. On the contrary, it is intended for the subject matter of the invention to include all alternatives, modifications and equivalents as can be included within the spirit and scope of the following claims.

Further, it is the inventor's intent to retain all equivalents of the claimed invention even if the claims are amended during prosecution.

What is claimed is:

1. A surface emitting laser, comprising:
a semiconductor substrate;
a first reflector formed on the semiconductor substrate;
an active layer formed on the first reflector;
a tunnel junction layer formed above a part of the active layer;
a semiconductor spacer layer which covers the tunnel junction layer;
a second reflector formed on the semiconductor spacer layer in a region above the tunnel junction layer;
a first electrode formed in a periphery of the second reflector on the semiconductor spacer layer; and
a second electrode electrically connected to a layer lower than the active layer,
wherein a layer thickness of the semiconductor spacer layer in the region directly above the tunnel junction layer is thinner than the layer thickness of the semiconductor spacer layer in the region directly below the first electrode.

2. The surface emitting laser according to claim 1, wherein the semiconductor spacer layer is in the concave shape with a recess sank in the tunnel junction layer direction in a region directly above the tunnel junction layer.

3. The surface emitting laser according to claim 1, wherein the second electrode is electrically connected to the first reflector.

4. The surface emitting laser according to claim 1, wherein the first electrode is alloyed ohmic electrode.

5. The surface emitting laser according to claim 1, wherein a distance in the direction vertical to a surface of the semiconductor substrate between the first electrode and a center plane of the active layer is at least 1.0 μm or more.

6. The surface emitting laser according to claim 1, wherein a distance in the direction vertical to a surface of the semiconductor substrate between the second reflector and a center plane of the active layer in a region directly above the tunnel junction layer is approximately 1λ in optical thickness, where the λ is a length inside a medium of the lasing wavelength.

7. The surface emitting laser according to claim 1, wherein a distance between the first reflector and the second reflector in a region directly above the tunnel junction layer is approximately 3λ/2 in optical thickness, where the λ is a length inside a medium of the lasing wavelength.

8. The surface emitting laser according to claim 1, wherein a distance between the first reflector and second reflector in the region directly above the tunnel junction layer is 5λ/2 or less in optical thickness, where the λ is a length inside a medium of the lasing wavelength.

9. The surface emitting laser according to claim 1, wherein a variance in the layer thickness of the semiconductor spacer layer in the region of above the tunnel junction is λ/10 or less in optical thickness, where the λ is a length inside a medium of the lasing wavelength.

10. The surface emitting laser according to claim 1, wherein at least one of the first and second reflectors is a distributed Bragg reflector comprising a laminated structure with a semiconductor layer and a dielectric layer or a distributed Bragg reflector comprising a periodic structure of the air space in the semiconductor layer.

11. The surface emitting laser according to claim 1, wherein at least one of the first and second reflectors is a subwavelength diffractive grating.

12. The surface emitting laser according to claim 1, wherein the semiconductor spacer layer is a first conductive type semiconductor spacer layer, and the surface emitting laser comprises a second conductive type semiconductor spacer layer between the active layer and the tunnel junction layer.

13. The surface emitting laser according to claim 12, wherein the first conductive type is an n-type, and the second conductive type is a p-type.

14. The surface emitting laser according to claim 13,
wherein the semiconductor substrate is a compound semiconductor substrate containing Ga and As.

15. The surface emitting laser according to claim 1,
wherein the semiconductor spacer layer contains In.

16. The surface emitting laser according to claim 1,
wherein a material used in a well layer of a semiconductor quantum-well-structure forming the active layer is an InGaAs compound semiconductor.

17. The surface emitting laser according to claim 1,
wherein a lasing wavelength of the surface emitting laser is approximately 1.0 μm to 1.34 μm.
